(19) United States
(12) Patent Application Publication
(10) Pub. No.: US 2024/0088029 A1
(43) Pub. Date: Mar. 14, 2024

(54) FULL WAFER DEVICE WITH BACK SIDE INTERCONNECTS AND WAFER-SCALE INTEGRATION

(71) Applicant: Intel Corporation, Santa Clara, CA (US)

(72) Inventors: Abhishek A. Sharma, Hillsboro, OR (US); Tahir Ghani, Portland, OR (US); Wilfred Gomes, Portland, OR (US); Anand S. Murthy, Portland, OR (US); Sagar Suthram, Portland, OR (US)

(73) Assignee: Intel Corporation, Santa Clara, CA (US)

(21) Appl. No.: 17/930,841

(22) Filed: Sep. 9, 2022

(51) Int. Cl. H01L 23/528; H01L 23/522

(52) U.S. Cl. CPC H01L 23/528; H01L 23/5226

(57) ABSTRACT

Described herein are full wafer devices that include interconnect layers on a back side of the device. The backside interconnect layers couple together different dies of the full wafer device. The backside interconnect layers include an active layer that includes active devices, such as transistors. The active devices may act as switches, e.g., to control routing of signals between different dies of the full wafer device.

### BACKGROUND

For the past several decades, the scaling of features in ICs has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each IC die and each IC package that includes one or more dies becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B illustrate example perspective views and side views of dies formed over a wafer, according to some embodiments of the present disclosure.

FIGS. 2A-2C illustrate a fabrication process for a full-wafer device with backside interconnects, according to some embodiments of the present disclosure.

FIGS. 3A and 3B provide two cross-sections of a full wafer device with an active layer in the backside interconnect structure, according to some embodiments of the present disclosure.

FIGS. 4A-4E illustrate a process for layer transfer, according to some embodiments of the present disclosure.

FIG. 5 is a cross-section view of an example passive electronic component with a seam, according to some embodiments of the present disclosure.

FIGS. 6A and 6B are top views of, respectively, a wafer and dies that may include one or more passive devices in accordance with any of the embodiments disclosed herein.

FIG. 7 is a cross-sectional side view of an IC package that may include one or more passive devices in accordance with any of the embodiments disclosed herein.

FIG. 8 is a cross-sectional side view of an IC device assembly that may include one or more passive devices in accordance with any of the embodiments disclosed herein.

FIG. 9 is a block diagram of an example computing device that may include one or more passive devices in accordance with any of the embodiments disclosed herein.

### DETAILED DESCRIPTION

Overview

In traditional semiconductor processing, multiple dies are formed over the surface of a semiconductor wafer. Each of the dies may be a repeating unit of a semiconductor product, such as an integrated circuit (IC) device. Typically, after the ICs are formed in the dies, the wafer undergoes a singulation process in which each of the dies is separated from one another to provide discrete “chips” of the IC device.

To achieve greater computational power, multiple dies can be packaged together and interconnected. Wafer-scale integration can be used to interconnect all of the dies on a wafer, forming a very powerful device, such as a supercomputer. A device that uses the full wafer can also be referred to as a full wafer engine or full wafer device. In some cases, circuitry arranged as multiple dies is fabricated on a wafer. Rather than singulating the dies, additional layers of interconnect are formed over the dies to connect the individual dies together, forming a full wafer device.

Due to manufacturing constraints, it can be challenging to produce a wafer in which each of the dies is not defective. In generating high-density circuits with increasingly small features, it is typical for a portion of the resulting dies to have some flaws. As an alternative to using a full, processed wafer, multiple singulated dies may be bonded to a wafer. The dies may be tested before bonding to the wafer to ensure functionality of each of the dies in the final device. Interconnect circuitry can then be fabricated over this assembly of dies to connect the individual dies together.

Interconnect circuitry formed over a wafer level device typically includes only passive circuitry and devices. For example, interconnect structures, e.g., vias and trenches, in an interconnect layer transmit signals but do not actively control the routing of signals. Other passive structures, such as resistors, capacitors, and/or inductors, may be incorporated in an IC package to reduce electromagnetic interference (EMI) and/or suppress electrostatic discharge (ESD).

Embodiments of the present disclosure may provide active switching between different portions of a full wafer device within the interconnect layers. For example, global interconnect layers couple together multiple dies of the full-wafer device, routing signals from one die to another die, providing full wafer integration. As disclosed herein, the global interconnect layers may include active devices, e.g., transistors, to control transmission of signals within the global interconnect layers. This can improve computing power and efficiency of a full wafer device.

More specifically, the global interconnect layers may be on a back side of a full wafer device, and one or more active layers may be formed within the global interconnect layers on the back side of the full wafer device. At one stage in a fabrication process, a wafer may include a support structure, and multiple dies over the support structure (e.g., on a front face of a semiconductor substrate). Each die may include both logic structures (e.g., one or more layers of transistors) and local interconnect structures coupled to the logic structures. In some embodiments, some or all of the dies may include additional components, such as memory devices or passive devices.

The front side of the wafer may be coupled to a carrier structure. The substrate holding the dies may be fully or partially removed. Backside interconnect layers are then formed on the back side of the dies, e.g., on the back side of the logic layers. One or more active layers, e.g., layers of transistors, may be formed among the backside interconnect layers to provide active switching in the global communications channels. The active layer(s) may include, for example, thin-film transistors (TFTs) fabricated over an interconnect layer. In some embodiments, a layer of single-crystal material is layer transferred over a global interconnect layer, and transistors are formed in or over the single-crystal layer. In some embodiments, signal and/or power vias extend through the active layer(s). In some embodiments, passive devices are also formed in the backside global interconnect layers. The passive devices may be formed by additive processing, resulting in a seam observable in a cross section of the device.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods and devices of this disclosure each have several innovative aspects, no single one of which is solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

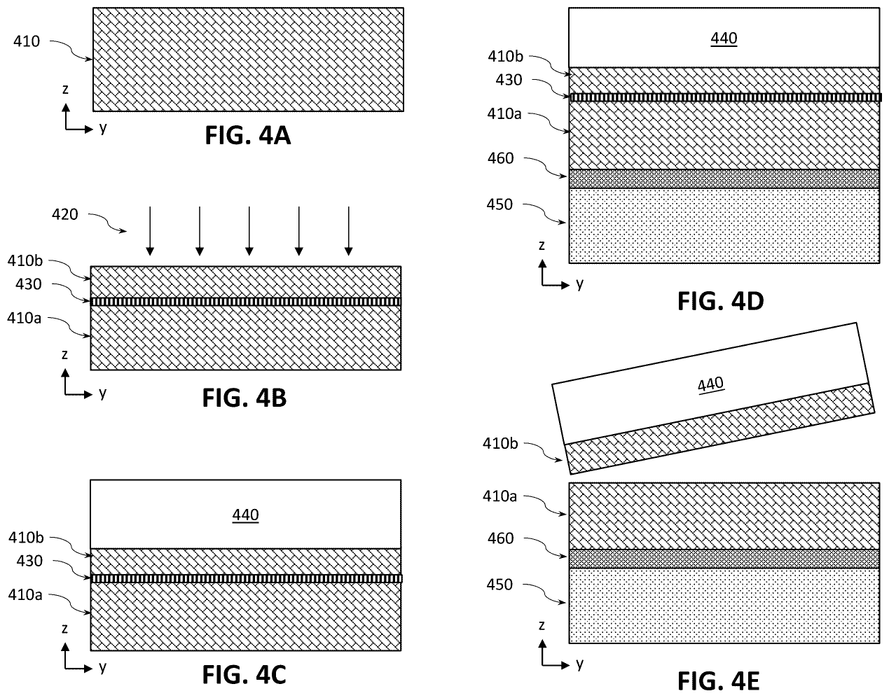

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 4A-4E, such a collection may be referred to herein without the letters, e.g., as “FIG. 4.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with stacked memory devices as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Example Wafer Device with Multiple Dies

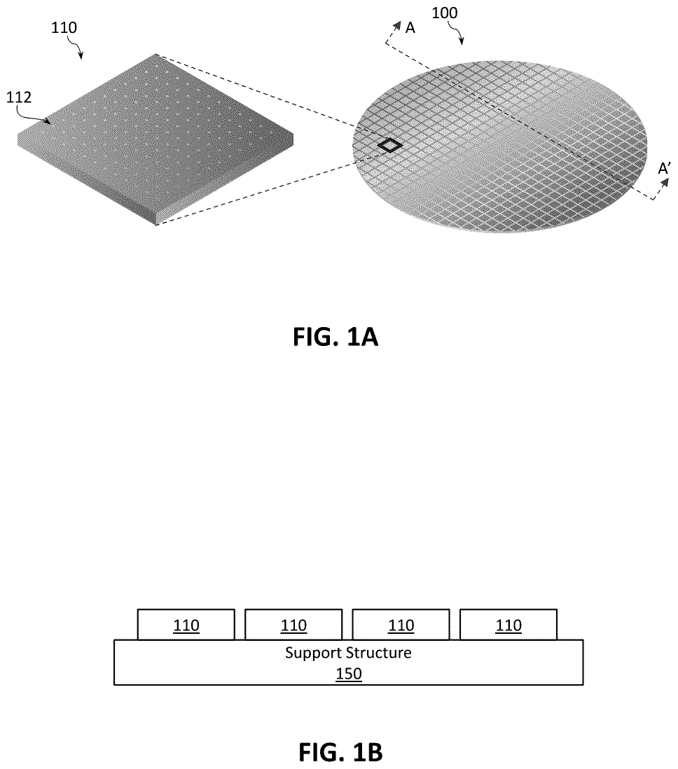

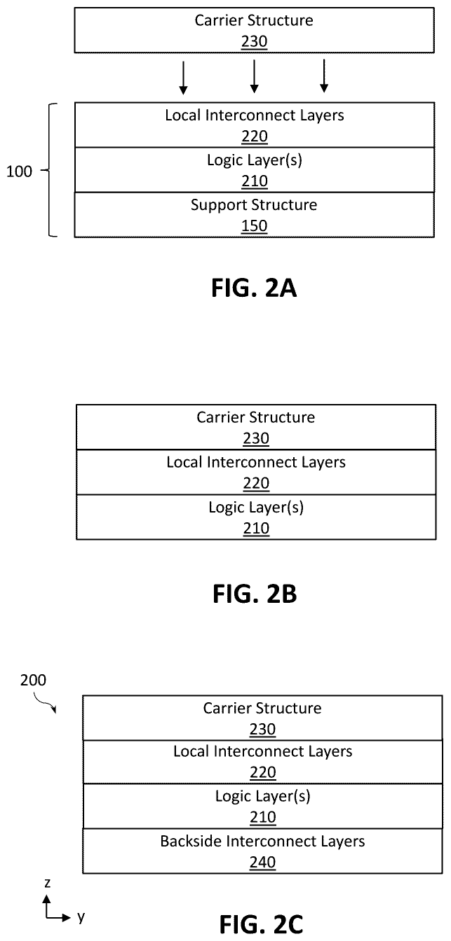

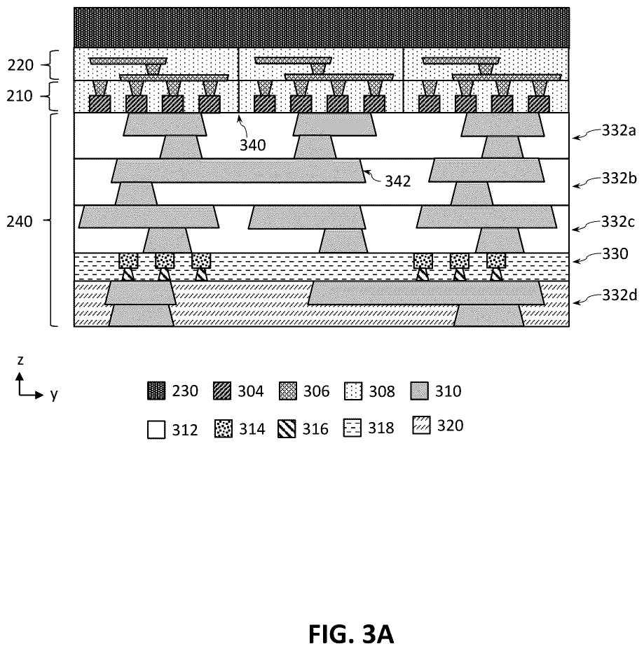

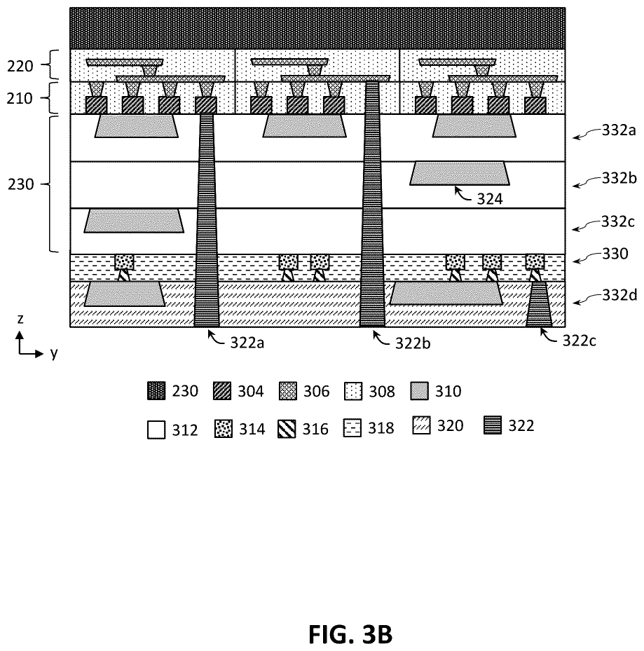

FIGS. 1A and 13 illustrate example perspective views and side views of dies formed over a wafer, according to some embodiments of the present disclosure. The wafer 100 may be generally circular or approximately circular. As described herein and illustrated in FIGS. 2 and 3, the wafer 100 may be coupled to a global interconnect structure to form a full wafer device. The global interconnect structure may be formed as multiple layers (e.g., multiple metal layers), and one or more active layers (e.g., one or more semiconductor layers) that include active devices, such as transistors.

The wafer 100 may be composed of semiconductor material and include multiple dies having IC structures formed on a surface of the wafer 100. One of the dies 110 is labelled and enlarged in FIG. 1A, but a plurality of similar dies are shown to be arranged in a grid-like manner across the wafer 100. Each of the dies of the wafer 100 may be a repeating unit of a semiconductor product that includes any suitable IC. The dies 110 may include semiconductor devices for implementing computing logic, e.g., transistors and/or capacitors. Individual dies 110 may further include circuitry for connecting these devices, e.g., interconnect circuitry that may include lines (or trenches) and vias. The interconnect circuitry is typically formed from conductive materials, and may be formed in one or more interconnect layers, also referred to as metal layers. Within a given die, the interconnect layers are referred to herein as local interconnect layers, meaning that the interconnect structures are local to a die 110, rather than extending between multiple dies. The semiconductor devices may be formed in one or more layers, which may be referred to as a logic layer or device layer. The dies 110 may be rectangular or square shaped. The dies 110 may be separated from each other by small spaces (e.g., less than 500 microns, or less than 200 microns) forming a grid, visible in FIG. 1A. These spaces are referred to as scribe lines, and typically do not include active circuitry.

The enlarged die 110 of FIG. 1A further illustrates signal vias 112, only one of which is labeled in FIG. 1A with a reference numeral, but a plurality of which are shown in FIG. 1A to be arranged in a grid-like manner. The signal vias 112 may extend in or through the die 110 in order to communicate signals to, from, or between various IC components (e.g., transistors, resistors, capacitors, interconnects, etc.) of the die 110. For example, the signal vias 112 may communicate signals to/from/between transistors implementing compute logic if the die 110 is a compute die. At least a portion of the signal vias 112 may also connect to interconnect structures outside the compute die 110, e.g., as discussed in relation to FIG. 2.

FIG. 1B illustrates an example cross-section of a wafer 100, taken through the plane AA′ illustrated in FIG. 1A. In this example, the wafer 100 includes a support structure 150 over which multiple dies 110 are formed. While four dies 110 are illustrated in FIG. 1B, it should be understood that more dies, or fewer dies, maybe included in the cross-section. In this example, the dies 110 are arranged over the support structure 150. For example, the dies 110 may be fabricated, tested, and mounted onto the support structure 150. Alternatively, the dies 110 may be built up over the support structure 150. In other embodiments, the dies 110 may be formed fully or partially in the support structure 150, rather than resting on top of the support structure 150.

The support structure 150 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which a full wafer device as described herein may be built falls within the spirit and scope of the present disclosure.

FIGS. 2A-2C illustrate a fabrication process for a full-wafer device with backside interconnects, according to some embodiments of the present disclosure. FIG. 2A provides a schematic illustration of the wafer 100 being coupled to a carrier structure 230. The wafer 100 includes the support structure 150 described in relation to FIG. 1. The wafer 100 further includes one or more logic layers 210 and one or more local interconnect layers 220. The logic layers 210 and local interconnect layers 220 may include the dies 110 shown in FIGS. 1A and 13. The logic layers 210 may be computing logic layers that may include logic transistors and/or other logic devices. As described with respect to FIGS. 1A and 1B, the local interconnect layers 220 and logic layers 210 may be arranged in a plurality of dies (e.g., the dies 110). The local interconnect layers 220 connect to circuitry within a given die, i.e., each die 110 has a local interconnect structure in the local interconnect layers 220 coupled to logic in the logic layers 210. The local interconnect structures are not coupled between two or more dies. The logic layers 210 and local interconnect layers 220 may form a logic IC. In some embodiments, additional types of structures, such as memory devices, optical devices, passive circuitry, etc., may be included in the logic layers 210, local interconnect layers 220, and/or additional layers not depicted in FIG. 2. While the local interconnect layers 220 are depicted as being formed over the logic layers 210, in some embodiments, one or more local interconnect layers 220 may be formed below a logic layer 210 (e.g., between a logic layer 210 and the support structure 150). In some embodiments, one or more interconnect layers 220 may be interspersed between two logic layers 210.

The support structure 150 has a front side and a back side, where the back side forms the back of the wafer 100. The logic layer 210 is formed over the front side of the support structure 150. The logic layer 210 likewise has a front side and a back side, where, in this example, the back side is adjacent to the support structure 150, and the front side is coupled to the local interconnect layers 220. The support structure 150, logic layers 210, and local interconnect layers 220 form the wafer 100 shown in FIG. 1. As illustrated in FIG. 2A, a carrier structure 230 is coupled to the front side of the wafer 100. The carrier structure 230 may be similar to the support structure 150 described above. More generally, the carrier structure 230 may be a wafer or another structure suitable for attaching to the wafer 100 and supporting the logic layers 210 and local interconnect layers 220. The carrier structure 230 may be bonded to the front side of the wafer 100 using an adhesive material, heat, pressure, or a combination of techniques for bonding the carrier structure 230 to the wafer.

After the carrier structure 230 has been bonded to the wafer 100, the support structure 150 may be removed from the back side of the device, as illustrated in FIG. 2B. The support structure 150 may be removed by grinding and polishing, for example. In some embodiments, a portion of the support structure 150 is removed, while a portion of the support structure 150 remains attached to the logic layer 210.

After the support structure 150 has been fully or partially removed, backside interconnect layers 240 are fabricated on the back side of the device, as shown in IFG. 2C. The backside interconnect layers 240, logic layer(s) 210, and local interconnect layers 220 form a full wafer device 200. In the example shown in FIG. 2C, the carrier structure 230 remains on the front of the full wafer device 200. In other embodiments, some or all of the carrier structure 230 is removed. For example, the backside interconnect layers 240 may be sufficiently thick to support the full wafer device 200, and the carrier structure 230 may be removed.

The backside interconnect layers 240 include interconnect structures that couple two or more dies together. These interconnect structures may be referred to as global interconnects, and the backside interconnect layers 240 may be referred to as global interconnect layers. In this example, the backside interconnect layers 240 are formed below the logic layer(s) 210. Electrical signals, such as power and/or input/output (I/O) signals, may be routed to and/or from the logic layer 210 through the backside interconnect layers 240. For example, electrically conductive features of the logic layer 210 (e.g., gates and source/drain (S/D) contacts of transistors in the logic layer 210) may be electrically coupled with the interconnect structures in the backside interconnect layers 240 to enable die-to-die communication in the full wafer device 200. In other embodiments, interconnect structures in the backside interconnect layers 240 may be coupled to interconnect structures in the local interconnect layers 220 by vias through the logic layer(s) 210, and the local interconnect layers 220 are in turn electrically coupled to the electrically conductive features of the logic layer 210. In addition to interconnect structures, the backside interconnect layers 240 may include one or more layers of active devices. An example active device layer is illustrated in FIGS. 3A and 3B.

Interconnect structures in the local interconnect layers 220 and backside interconnect layers 240 may be arranged in various layers to route electrical signals according to a wide variety of designs. In some embodiments, the interconnect structures may include trench structures (sometimes referred to as “lines”) and via structures (sometimes referred to as “holes”) filled with an electrically conductive material such as a metal. Trench structures may be arranged to route electrical signals in a direction of a plane that is substantially parallel with a surface of the full wafer device 200 (e.g., parallel to the logic layer 210), while via structures may be arranged to route electrical signals in a direction of a plane that is substantially perpendicular to a surface of the full wafer device 200 (e.g., parallel to the logic layer 210). Example trench and via structures are illustrated in FIGS. 3A and 3B.

In some embodiments, the backside interconnect layers 240 may be fabricated in a separate process from the logic layers 210 and/or local interconnect layers 220. For example, in a first fabrication process, die-level structures including the logic layers 210 and local interconnect layers 220 are formed over the support structure 150 to produce a wafer with multiple dies, as illustrated in FIGS. 1 and 2A. In a second fabrication process, wafer-level structures, including the global interconnect layers 240, are formed on the back side to produce the full wafer device 200, e.g., as shown in FIGS. 2B and 2C.

In some embodiments, the die-level structures are first formed over a first support structure, and the dies are then singulated to provide discrete “chips” containing the die-level structures. The singulated dies may be tested, and accepted dies are assembled over the support structure 150 to produce the wafer 100. Then, the wafer-level structures, including the backside interconnect layers 240, are formed on the back side of the reassembled dies to produce the full wafer device 200.

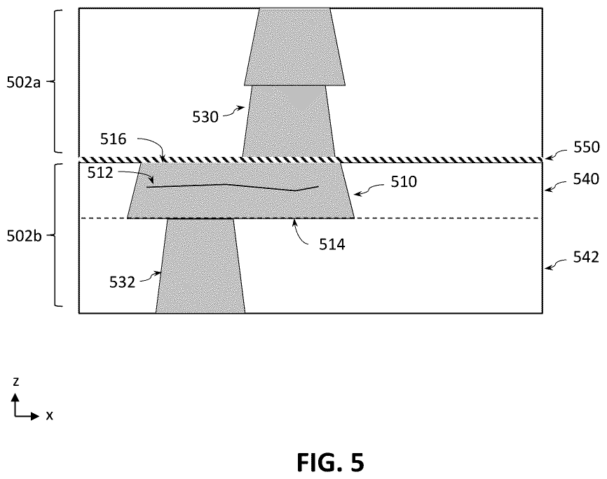

The full wafer device 200 may include passive devices, including resistors, inductors, and/or capacitors. For example, passive devices may be included in the full wafer device 200 to reduce EMI and/or suppress ESD in the device. Passive devices may be formed in any of the metal layers, e.g., in one or more of the backside interconnect layers 240 and/or one or more of the local interconnect layers 220. The passive devices may be formed using an additive process, e.g., by removing portions of dielectric material to form regions where the passive devices are to be formed, and depositing a metal or other conductive material into these regions. This additive process may result in a seam within the passive device that can be observed in a cross-section of the full wafer device 200, e.g., in a cross-section taken in a plane parallel to the z-direction and perpendicular to the logic layer 210. An example seam is shown in FIG. 5 and described further below.

Example Cross-Sections of Wafer Device with Active Backside Layer

FIGS. 3A and 3B provide two cross-sections of a full wafer device with an active layer in the backside interconnect structure, according to some embodiments of the present disclosure. FIG. 3A shows a first cross-section in an x-z plane in the orientation of FIGS. 2C and 3A. FIG. 3B shows a second cross-section in a different x-z plane, i.e., a plane at a different position along a y-axis (into or out of the page). FIGS. 3A and 3B illustrate cross sections of the logic layer 210, the local interconnect layers 220, the carrier structure 230, and the backside interconnect layers 240. As noted above, in some embodiments, the carrier structure 230 may not be present. Furthermore, the arrangement of the logic layer 210 and local interconnect layers 220 may be different, e.g., one or more local interconnect layers 220 may be on a back side of the logic layer 210.

A number of elements referred to in the description of FIGS. 3A and 3B with reference numerals are illustrated in these figures with different patterns, with a legend showing the correspondence between the reference numerals and patterns being provided at the bottom of the drawing pages. For example, the legend in FIG. 3A illustrates that FIG. 3A uses different patterns to show a carrier structure 230, first logic devices 304, a first conductive material 306, a first dielectric material 308, a second conductive material 310, a second dielectric material 312, second logic devices 314, contacts 316, a third dielectric material 318, a fourth dielectric material 320. FIG. 3B further includes a via material 322.

As shown in FIGS. 3A and 3B, the wafer device 200 may include one or more, typically a plurality, of interconnect structures formed from the first conductive material 306 in the local interconnect layer 220. The wafer device 200 further includes one or more, typically a plurality, of interconnect structures formed from the second conductive material 310 in the backside interconnect layers 240. The interconnect structures in the local interconnect layer 220 connect devices (e.g., transistors 304) within a given die. Scribe lines, e.g., scribe line 340, are illustrated between adjacent dies, which are examples of the dies 110. The interconnect structures in the backside interconnect layers 240 may span multiple dies. For example, the interconnect structure 342 spans two dies separated by the scribe line 340. The interconnect structure 342 can transmit signals between logic devices of two different dies of the wafer device 200. The backside interconnect layers 240 include four metal layers, referred to as 332a, 332b, 332c, and 332d. The backside interconnect layers 240 further includes an active layer 330.

The active layer 330 includes logic devices 314, e.g., transistors. The second logic devices 314 may be different from the first logic devices 304, e.g., the logic devices 304 and the logic devices 314 may include different materials and/or may have different architectures. The logic devices 314 may include a wide variety of configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors. The logic devices 314 may be thin film transistors (TFTs), described further below in relation to logic devices 304.

The logic devices 314 may act as switches that can be configured to control connectivity between different logic devices 304, e.g., between different dies of the full wafer device 200. For example, a logic device 314, or set of logic devices 314, may alternately couple a first die to a second die or to a third die. As shown in FIG. 3A, at least a portion of the logic devices 314 may coupled to interconnects in the backside interconnect layers 240. The logic devices 314 may be semiconductor devices coupled to a conductive material 316 forming contacts (e.g., source, drain, and/or gate contacts) to the logic devices 314. While the conductive material 316 is shown as being a different material from the conductive materials 306 and 310, in other embodiments, the conductive material 316 may be the same as one or both of the conductive materials 306 and 310.

The logic devices 314 are surrounded by a dielectric material 318 in the active layer 330. The dielectric material 318 may be different from any or all of the other dielectric materials 308, 312, and 320. For example, the dielectric material 318 may have a different dielectric constant from the dielectric material 312 and/or 320. Furthermore, in some embodiments, the dielectric materials 312 and 320 on either side of the active layer 330 may be different, e.g., they may have different dielectric constants. In some embodiments, the dielectric material 318 is deposited over a layer of the backside interconnect layers 240; in this example, the dielectric material 318 is deposited over the third metal layer 332c. Logic devices 314 are formed in and/or over the deposited dielectric material 318. For example, the logic devices 314 may be thin film transistors formed over the dielectric material 318.

In some embodiments, a layer of material is layer-transferred over a layer of the backside interconnect layers 240 (e.g., over the metal layer 332c in the example). If layer-transfer is performed, a bonding material may be present between the metal layer 332c and the active layer 330. In one example, a layer of single-crystal semiconductor material may be layer-transferred over the metal layer 332c. Portions of the single-crystal semiconductor may form active devices, e.g., transistors; other portions of the single-crystal material may be etched and filled with the dielectric material 318. The remaining single-crystal structures (e.g., a single-crystal material in a logic device 314) may have a grain size of at least 100 nanometers. An example layer transfer process is illustrated in FIGS. 4A-4E.

After the transistors 314 are formed, additional interconnect layers (e.g., the metal layer 332d) may be formed over the active layer 330. Thus, the active layer 330 may be between two backside interconnect layers 240. While one active layer 330 is illustrated in FIGS. 3A and 3B, in some embodiments, two or more active layers 330 may be included. Furthermore, in other embodiments, the relative position of the active layer 330 and the metal layers 332 may be different.

In some embodiments, certain portions of the first conductive material 306 and/or second conductive material 310 may form one or more passive devices. For example, in FIG. 3B the conductive material 310 forms a first passive device 324 in a backside interconnect layer 240, and in particular, in the second metal layer 332b. In other examples, the local interconnect layers 220 may include one or more passive devices. In general, passive devices may be formed in different ones of the interconnect layers 220 and 240. For example, a passive device may span multiple metal layers, e.g., an inductor may include coils formed in the metal layers 332b and 332c. In some embodiments, a passive device may include multiple layered structures within a single metal layer. For example, the conductive material 310 may be formed into two parallel plates, stacked over each other in the z-direction, in a single metal layer 332 to form a capacitor.

More generally, in the wafer device 200, the interconnects and, in some cases, passive devices may be arranged in one or more, typically a plurality, of layers of a metallization stack, where each layer may include an insulating material 308, 312, or 320 (e.g., a dielectric material formed in multiple layers, as known in the art). The interconnects may include one or more conductive traces and conductive vias, providing one or more conductive pathways through the insulating materials 308, 312, and 320. The conductive materials 306 and 310 may include any appropriate conductive material, such as copper, silver, nickel, gold, aluminum, or other metals or alloys, for example. The conductive pathways formed by the conductive material 306 may be connected to one another in any suitable manner. Similarly, the conductive pathways formed by the conductive material 310 may be connected to one another in any suitable manner. Although FIGS. 3A and 3B illustrate a specific number and arrangement of conductive pathways formed by the conductive materials 306 and 310, these are simply illustrative, and any suitable number and arrangement may be used.

In some embodiments, at least one of the insulating materials 308, 312, 318, and 320 may include a dielectric material, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, at least one of the insulating materials 308, 312, 318, and 320 may include a semiconductor material, such as silicon, germanium, or a III-V material (e.g., gallium nitride), and one or more additional materials. For example, at least one of the insulating materials 308, 312, 318, and 320 may include silicon oxide or silicon nitride.

In some embodiments, any of the insulating materials 308, 312, 318, and 320 is a different material from at least one other of the insulating materials 308, 312, 318, and 320. For example, the insulating materials 308 and 312 may have different k-values. In other embodiments, one or more of the insulating materials 308, 312, 318, and 320 may be a same material. Likewise, as shown in FIGS. 3A and 3B, the first conductive material 306 is a different material from the second conductive material 310. In other embodiments, the conductive materials 306 and 310 may be a same material.

In some embodiments, conductive materials 306 and/or 310 may form conductive pathways to route power, ground, and/or signals to/from various components of the logic layer 210, the active layer 330, and/or to the passive devices formed in the local and/or backside interconnect layers 220 and 240. For example, the wafer device 200 may include conductive vias extending through one or more backside layers (e.g., through the backside interconnect layers 240, including the active layer 330) to the logic layer 210. FIG. 3B illustrates vias 322, at least a portion of which extend through the backside interconnect layers 240, including the active layer 330. In particular, a first example via 322a extends through the backside interconnect layers 240, including the active layer 330, and is coupled to the logic layer 210. The first example via 322a be a power via for providing power to the logic layer 210, or the first example via 322a may be a signal via for transmitting signals to or from the logic layer 210. A second example via 322b is coupled to an interconnect structure in a local interconnect layer 220. The second example via 322b may communicate a signal to and/or from the local interconnect layer 220. A third example via 322c is coupled to the active layer 330. The third example via 322c may be a signal via for transmitting signals to or from the active layer 330, or the third example via 322c may be a power via for delivering power to the active layer 330. The vias 322 may be isolated from the surrounding silicon or other semiconductor material by a barrier oxide.

More generally, the conductive pathways formed by vias 322 may route power, ground, and/or signals between various points on the wafer device 200, including one or more of the backside interconnect layers 240, the active layer 330, the logic layer 210, and the local interconnect layer 220, and a power and/or signal delivery device located “below” the wafer device 200. In some embodiments, the wafer device 200 may be the source and/or destination of signals communicated between the wafer device 200 and one or more devices coupled to the wafer device 200.

The logic layer 210 includes logic devices 304, e.g., transistors, coupled to the local interconnect layer 220, e.g., through vias formed from the first conductive material 306 or another conductive material. The logic layer 210 may include semiconductor material systems including, for example, N-type or P-type materials systems, as active materials (e.g., as channel materials of transistors). In some embodiments, logic devices 304 may include substantially monocrystalline semiconductors, such as silicon or germanium.

In some embodiments, the logic devices 304 may include compound semiconductors, e.g., compound semiconductors with a first sub-lattice of at least one element from group III of the periodic table (e.g., Al, Ga, In), and a second sub-lattice of at least one element of group V of the periodic table (e.g., P, As, Sb). In some embodiments, the logic devices 304 may include a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

In some embodiments, the logic devices 304 may be/include an intrinsic IV or III-V semiconductor material or alloy, not intentionally doped with any electrically active impurity. In alternate embodiments, nominal impurity dopant levels may be present within the logic devices 304, for example to set a threshold voltage Vt, or to provide halo pocket implants, etc. In such impurity-doped embodiments however, impurity dopant level within the active materials may be relatively low, for example below about 10¹⁵ cm⁻³, and advantageously below 10¹³ cm⁻³.

For exemplary P-type transistor embodiments, logic devices 304 may advantageously be formed using group IV materials having a high hole mobility, such as, but not limited to, Ge or a Ge-rich SiGe alloy. For some exemplary embodiments, such active materials may have a Ge content between 0.6 and 0.9, and advantageously is at least 0.7.

For exemplary N-type transistor embodiments, the logic devices 304 may advantageously be formed using a III-V material having a high electron mobility, such as, but not limited to InGaAs, InP, InSb, and InAs. For some such embodiments, the active material may be a ternary III-V alloy, such as InGaAs or GaAsSb. For some InₓGa₁₋ₓAs fin embodiments, In content in the such active material may be between 0.6 and 0.9, and advantageously at least 0.7 (e.g., Ina_{0.7}Ga_{0.3}As).

In some embodiments, the logic devices 304 may be formed from thin-film materials, in which embodiments the logic devices 304 could be thin-film transistors (TFTs). A TFT is a special kind of a field-effect transistor (FET), made by depositing a thin film of an active semiconductor material, as well as a dielectric layer and metallic contacts, over a support structure that may be a non-conducting (and non-semiconducting) support structure. During operation of a TFT, at least a portion of the active semiconductor material forms a channel of the TFT, and, therefore, the thin film of such active semiconductor material is referred to herein as a “TFT channel material.” This is different from conventional, non-TFT, transistors where the active semiconductor channel material is typically a part of a semiconductor substrate, e.g., a part of a silicon wafer. In various such embodiments, active materials of the devices 304 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide.

In general, active materials of the logic devices 304 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

Example Layer Transfer Process

FIGS. 4A-4E illustrate a process for layer transfer, according to some embodiments of the present disclosure. The illustrated layer transfer process may be used during fabrication of the full wafer device 200, e.g., to transfer a material for forming the active layer 330 onto one of the backside interconnect layers 240.

FIG. 4A illustrates a monocrystalline material 410, e.g., a monocrystalline material for forming the active layer 330. Alternatively, the monocrystalline material 410 may be used to form an isolation layer, e.g., an isolation layer over which a single-crystal layer is deposited. The monocrystalline material 410 is formed as a sheet that extends in an x-direction (into and/or out of the page) and in the y-direction, labelled in FIG. 4. The monocrystalline material 410 may have a height in the z-direction of up to 1 millimeter. While the monocrystalline material 410 is depicted as a single material having a single crystal structure, in some embodiments, the monocrystalline material 410 includes multiple layers of monocrystalline materials, e.g., a single-crystal silicon layer formed over a single-crystal sapphire layer. In such embodiments, the lower layer may be an isolation layer, such that an isolation layer and a semiconductor layer are transferred onto the wafer in a single layer transfer process.

In FIG. 4B, a material 420 is implanted into a region 430 of the monocrystalline material 410. The implant material 420 weakens the implant region 430, e.g., by forming cracks in the implant region 430 of the monocrystalline material 410. The implant region 430 is formed as a layer between a lower portion 410a and an upper portion 410b of the monocrystalline material 410. The implant region 430 may be, e.g., between 50 nm and 500 nm from a front face of the monocrystalline material 410. The implant material 420 is electrically inert and does not change the electrical properties of the monocrystalline material 410, e.g., the implant material 420 does not dope the monocrystalline material 410. The implant material 420 may be, for example, hydrogen, helium, nitrogen, or ammonium. In some embodiments, multiple implant materials 420 may be used. After the implant material 420 is implanted into the monocrystalline material 410, the monocrystalline material 410 may cured by applying heat for a period of time. The monocrystalline material 410 outside the region 430 (i.e., the upper portion 410b and lower portion 410a of the monocrystalline material) is not affected by the implant material 420, e.g., these portions 410a and 410b maintain the monocrystalline structure without cracks or other defects (or a minimal amount of defects).

In FIG. 4C, a carrier wafer 440 is bonded to the front face of the monocrystalline material 410, i.e., to the upper portion 410b of the monocrystalline material 410. A bonding material, not shown in FIG. 4, may be used to adhere the carrier wafer 440 to the monocrystalline material 410. In other embodiments, the monocrystalline material 410 is flipped, and the back face of the lower portion 410a is bonded to a carrier wafer 440.

In FIG. 4D, the back face of the monocrystalline material 410 (e.g., the base of the lower portion 410a) is bonded to a wafer 450 with a bonding material 460. For example, the wafer 450 may be the wafer 100 with some portion of the backside interconnect layers 240 (e.g., the layers 332a, 332b, and 332c) fabricated on the backside of the wafer 100. In the orientation of FIG. 4D, the wafer 450 is flipped relative to the assembly shown in FIGS. 3, so that the monocrystalline material 410 is bonded to the layer 332c.

The bonding material 460 may be an adhesive material that ensures attachment of the monocrystalline material 410 to the wafer 450. In some embodiments, the bonding material 460 may be an etch-stop material. In some embodiments, the bonding material may be both an etch-stop material and have suitable adhesive properties to ensure. Such a bonding interface may be recognizable as a seam or a thin layer in the full wafer device 200, using, e.g., selective area diffraction (SED). The bonding material 460 may have a lower crystallinity than the monocrystalline material 410, e.g., the bonding material 460 may be a polycrystalline or amorphous material 130. In some embodiments, a bonding material 460 is not used.

To bond the monocrystalline material 410 to the wafer 450, a suitable pressure may be applied, or the assembly may be heated up to a suitable temperature (e.g., to moderately high temperatures, e.g., between about 50 and 200 degrees Celsius) for a duration of time.

In FIG. 4E, the carrier wafer 440 and the upper portion 410b of the monocrystalline material are lifted off the wafer 450, leaving the lower portion 410a attached to the wafer 450. The lower portion 410a attached to the wafer 450 may be, e.g., between 10 nm and 500 nm. The cracks formed in the implant region 430 cause the monocrystalline material 410 to break between the upper portion 410b and the lower portion 410a. In some embodiments, after the carrier wafer 440 and upper portion 410b of the monocrystalline material are removed, the exposed front surface of the lower portion 410a is grinded and/or polished to reduce the height of the lower portion 410a and/or to produce a smooth surface for forming the optical structures.

In alternate embodiments, e.g., if the monocrystalline material 410 is suitably thick and mechanically stable, the carrier wafer 440 is not used. Instead, the monocrystalline material 410 may be flipped to bond the back face of the lower portion 410b to the wafer 450, and the upper portion 410a is lifted off wafer 450.

Example Seams in Passive Devices

As noted above, the local interconnect layers 220 and/or backside interconnect layers 240 may include passive devices. The passive devices may be formed using an additive process. The additive process for forming the passive devices may result in a seam that can be observed in a cross-section of the passive device, e.g., a cross-section in the x-z direction in the coordinate system used herein.

FIG. 5 is a cross-section view of an example passive electronic component with a seam, according to some embodiments of the present disclosure. FIG. 5 illustrates two example metallization layers 502a and 502b, which may correspond to two of the backside interconnect layers 240. In this example, a passive device 510 is formed in the second layer 502b. The passive device 510 is coupled to a via 530 in the first layer 502a, and a via 532 in the second layer 502b. The via 530 is further coupled to an interconnect (e.g., another via) in the first layer 502a. The via 532 may be coupled to another interconnect device not shown in FIG. 5. The arrangement in FIG. 5 is merely exemplary. For example, the passive device 510 may be coupled to two different interconnect structures in the first layer 502a.

As illustrated in FIG. 5, the passive device 510 has a seam 512 extending through the cross-section of the passive device 510. The seam 512 extends in a direction substantially parallel to the support structure 150 and the logic layer 210. The seam 512 may also extend at least in part in the y-direction, i.e., into and/or out of the page. Said another way, the seam 512 may be visible in another x-z cross-section of the passive device 510 taken at a different position in the y-direction. The seam 512 may be observed in the cross-section, e.g., in a SEM image or TEM image of the cross-section.

The seam 512 may be an artifact of an additive process used to form the passive device 510. For example, to fabricate the passive device 510, a first layer 540 of an insulating material (e.g., the insulating material 312) is deposited over the layer 502a. In some embodiments, an etch stop material 550 is deposited prior to depositing the first layer 540 of insulating material. The first layer 540 of the insulating material 312 is patterned, e.g., using a lithographic process. A second layer 542 of the insulating material 312 (or a different insulating material) is then deposited. In some embodiments, an etch stop material (not shown in FIG. 5) is deposited prior to depositing the second layer 542 of the insulating material. The dashed line in FIG. 5 indicates a boundary between the first layer 540 and the second layer 542. The second layer 542 of the insulating material 312 is patterned, e.g., using a lithographic process. A portion of the second layer 542 of the insulating material 312, and a portion of the first layer 540 of the insulating material 312, are etched based on the patterning. In particular, a portion of the second layer 542 corresponding to the via 532 is etched, and a portion of the first layer 540 corresponding to the passive device 510 is etched. Thus, a cavity corresponding to the via 532 and a cavity corresponding to the passive device 510 are formed. A material for forming the passive device 510 and the via 532 (e.g., the conductive material 310) is deposited into the etched areas using a conformal deposition process, such as atomic layer deposition (ALD).

In the conformal deposition process, the conductive material for forming the passive device 510 enters the first layer 540 through the hole formed for the via 532. The seam 512 is a discontinuity in the conductive material that forms the passive device. During the conformal deposition process, a portion of the conductive material builds up over a lower surface of the cavity for forming the passive device 510, and a portion of the conductive material builds up below an upper surface of the cavity for forming the passive device 510. These two sides meet near a center of the height of the passive device 510, forming the seam 512.

Each of the structures illustrated in FIG. 5 has a trapezoidal shape which may result by building the layers over the back side of the logic layer 210. For example, a cross-section of the passive device 512 has a back side 514, or base, parallel to the logic layer 210 and a front side 516, or top, parallel to the logic layer 210. The front side 516 is nearer to the logic layer 210 than the back side 514. A length of the back side 514 in the x-direction is longer than a length of the front side 516 in the x-direction. Similarly, a length of a back side of the vias (e.g., the vias 530 and 532) is longer than a length of a front side of the same via.

The passive device 510 may have a height in the z-direction extending from one side of the passive device 510 (e.g., the back side 514) to an opposite side of the passive device 510 (e.g., the front side 516) that is, for example, between 10 nanometers and 200 nanometers. As noted above, in some embodiments, the passive device 510 may comprise multiple layers (e.g., two parallel plates, or an inductor that extends across multiple metal layers or multiple sub-layers of a metal layer), and each layer of the passive device 510 may be between 10 and 200 nanometers. In such examples, the structure 510 may represent one portion of the passive device, e.g., a portion of an inductor coil, a portion of a resistor, or a capacitor plate.

The seam 512 may be formed within a range around a midpoint of the height of the passive device 510. For example, the range of possible locations for the seam 512 may be between 40% and 60% of the height of the passive device 510. For example, if the height of the passive device 510 is 100 nanometers, the seam 512 may be located between 40 nanometers and 60 nanometers from a base of the passive device 510 parallel to the logic layer 210.

In order to fill the passive device 510 with the conductive material during the conformal deposition process, a width of the via 532 (in particular, a width of the via 532 along the back side 514 of the passive device 510) may be greater than the height of the passive device 510. This is because the conductive material builds up along the sides of the via 532 while the conductive material fills the cavity for forming the passive device 510, so the via 532 has an opening while the passive device 510 is being deposited. After the passive device 510 is fully deposited, the conformal deposition may proceed to fully fill the cavity for forming the via 532.

In different embodiments, the seam 512 can form in various ways and may have different appearances in the cross-section. For example, the seam 512 may be an air gap between a lower portion of the passive device 510 (e.g., a portion closer to a support structure 150) and an upper portion of the passive device 510 (e.g., a portion farther from the support structure 150). As another example, the seam 512 is a discontinuity in the material structure (e.g., crystal structure or grain structure) between the lower portion and upper portion of the passive device 510. As yet another example, the seam 512 is formed by a chemical difference between the lower portion and the upper portion of the passive device 510. Alternatively, a material along the seam 512 may have a different chemical composition than other portions of the passive device 510 (e.g., a different percentage of oxygen, nitrogen, or another element from surrounding regions of the passive device 510).

In some embodiments, a seam may extend into a via formed over the passive device. For example, a further seam may extend extends upwards from the seam 512 and into the via 532, roughly forming an inverted T-shape. The seam may extend all the way up the via 532, or partially up the via 532.

### Example Devices

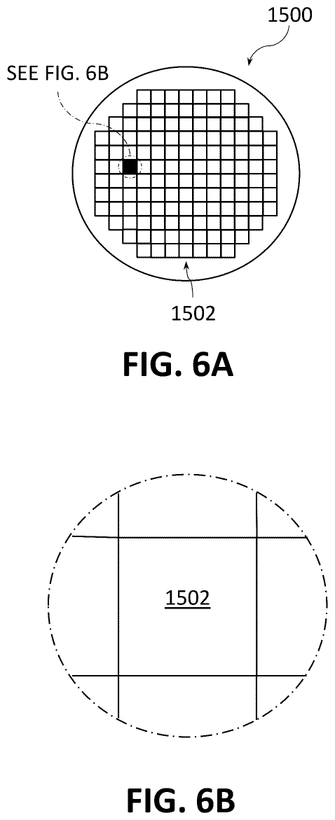

The full wafer device disclosed herein may be included in, or may include, any suitable electronic device. FIGS. 6-9 illustrate various examples of apparatuses that may include, or be included in, the full wafer devices disclosed herein.

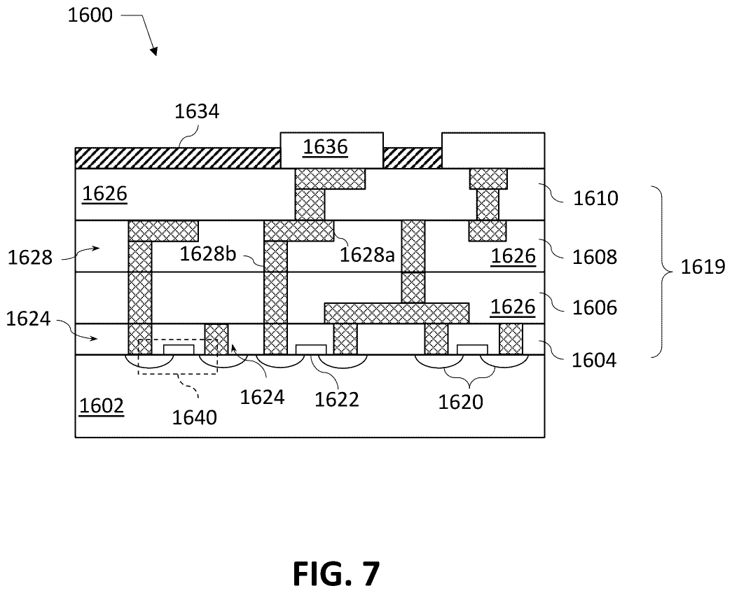

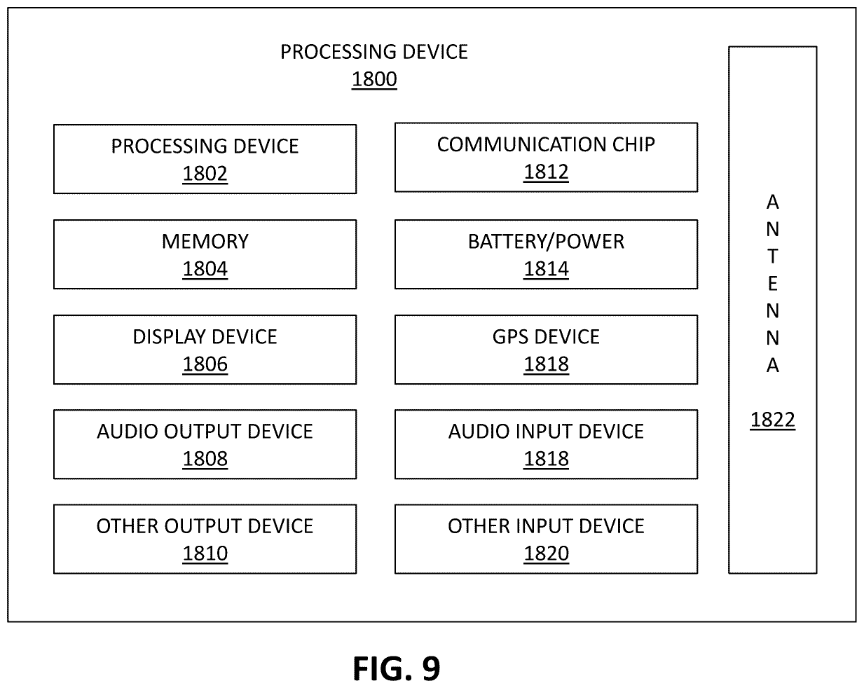

FIGS. 6A and 6B are top views of a wafer and dies that may form a full wafer device with an active layer in a backside interconnect structure in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-9, or any further embodiments of the IC structures described herein). After the fabrication of the semiconductor product is complete (e.g., after manufacture of one or more IC structures included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more IC structures may take the form of the wafer 1500 (e.g., not singulated) or the form of the die 1502 (e.g., singulated). The die 1502 may include one or more transistors (e.g., one or more of the transistors 1640 of FIG. 7, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

FIG. 7 is a cross-sectional side view of an IC device 1600 that may include one or more IC structures included in a full wafer device in accordance with any of the embodiments disclosed herein. The IC device 1600 may be formed on a substrate 1602 (e.g., the wafer 1500 of FIG. 6A) and may be included in a die (e.g., the die 1502 of FIG. 6B). The substrate 1602 may be any substrate as described herein. The substrate 1602 may be part of a singulated die (e.g., the dies 1502 of FIG. 6B) or a wafer (e.g., the wafer 1500 of FIG. 6A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 7). Although a particular number of interconnect layers 1606-1610 is depicted in FIG. 7, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 7. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 7. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

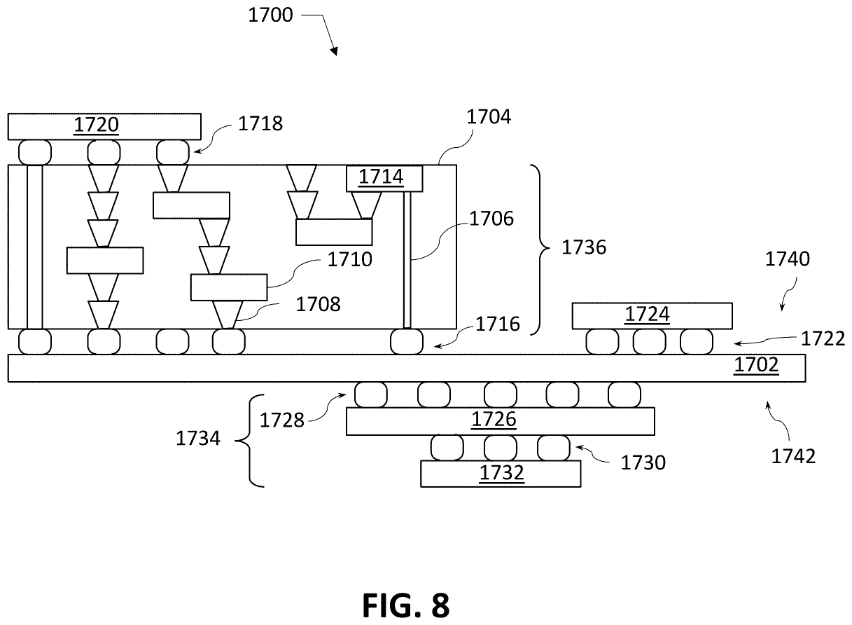

FIG. 8 is a cross-sectional side view of an IC device assembly 1700 that may be included in a full wafer device in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 6B), an IC device (e.g., the IC device 1600 of FIG. 7), or any other suitable component. In some embodiments, the IC package 1720 may be included in a full wafer device, e.g., as a die of a full wafer device, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 8, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example computing device 1800 that may include or be used in manufacturing a full wafer device in accordance with any of the embodiments disclosed herein. For example, any suitable ones of the components of the computing device 1800 may include a full wafer device as described herein. Any one or more of the components of the computing device 1800 may include, or be included in, an IC device 1600 (FIG. 7). Any one or more of the components of the computing device 1800 may include, or be included in, an IC device assembly 1700 (FIG. 8).

A number of components are illustrated in FIG. 9 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 9, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-M RAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides a device including a computing logic layer including a plurality of transistors; a local interconnect layer coupled to a first side of the computing logic layer; a plurality of global interconnect layers coupled to a second side of the computing logic layer, the second side opposite the first side; and a transistor layer formed between a first of the plurality of global interconnect layers and a second of the plurality of global interconnect layers, the transistor layer including a second plurality of transistors.

Example 2 provides the device of example 1, where the computing logic layer is arranged as a plurality of dies.

Example 3 provides the device of example 2, where interconnect structures in the local interconnect layer correspond to respective dies of the computing logic layer.

Example 4 provides the device of example 2 or 3, where a first of the plurality of dies has the same structure as a second of the plurality of dies.

Example 5 provides the device of any of examples 2-4, where a global interconnect structure of at least one of the plurality of global interconnect layers is coupled between two of the plurality of dies.

Example 6 provides the device of any of examples 2-5, where at least one transistor of the transistor layer forms a switch, the switch coupled between a first die and a second die of the plurality of dies.

Example 7 provides the device of any of the preceding examples, further including a power via extending through the transistor layer to the computing logic layer.

Example 8 provides the device of example 7, further including a signal via extending through the transistor layer to the computing logic layer.

Example 9 provides the device of any of the preceding examples, where the transistor layer includes thin-film transistors (TFTs).

Example 10 provides the device of any of examples 1-8, where the transistor layer includes a substantially monocrystalline material having a grain size of at least 100 nm.

Example 11 provides the device of example 10, further including a bonding layer coupling the transistor layer to one of the plurality of global interconnect layers.

Example 12 provides the device of any of the preceding examples, where a cross-section of a global interconnect structure in one of the plurality of global interconnect layers has a back side parallel to the computing logic layer and a front side parallel to the computing logic layer, the front side closer to the computing logic layer than the back side, where a length of the back side is longer than a length of the front side.

Example 13 provides the device of any of the preceding examples, where a first dielectric material in the first of the plurality of global interconnect layers is different from a second dielectric material in the second of the plurality of global interconnect layers.

Example 14 provides the device of example 13, where the first dielectric material has a first dielectric constant, and the second dielectric material has a second dielectric constant different from the first dielectric constant.

Example 15 provides a backside interconnect assembly including a plurality of backside interconnect layers coupled to a back side of a logic layer; and an active layer formed between a first of the plurality of backside interconnect layers and a second of the plurality of backside interconnect layers, the active layer including a plurality of transistors.

Example 16 provides the backside interconnect assembly of example 15, where the logic layer includes a plurality of dies, and the plurality of backside interconnect layers couple a first die of the logic layer to a second die of the logic layer.

Example 17 provides the backside interconnect assembly of example 15, where a logic device in the active layer alternatively couples a first die of the logic layer to a second die of the logic layer or to a third die of the logic layer.

Example 18 provides a device including a logic layer including a plurality of transistors; a first interconnect layer coupled to a first side of the logic layer, the first interconnect layer including a first dielectric; a second interconnect layer coupled to a second side of the logic layer, the second side opposite the first side, the second interconnect layer including a second dielectric different from the first dielectric; and a transistor layer coupled to the second interconnect layer.

Example 19 provides the device of example 18, further including a third interconnect layer coupled to the transistor layer, the transistor layer between the second interconnect layer and the third interconnect layer.

Example 20 provides the device of example 18, where the logic layer includes a plurality of dies.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A device comprising:
a computing logic layer comprising a plurality of transistors;
a local interconnect layer coupled to a first side of the computing logic layer;
a plurality of global interconnect layers coupled to a second side of the computing logic layer, the second side opposite the first side; and
a transistor layer formed between a first of the plurality of global interconnect layers and a second of the plurality of global interconnect layers, the transistor layer comprising a second plurality of transistors.

2. The device of claim 1, wherein the computing logic layer is arranged as a plurality of dies.

3. The device of claim 2, wherein interconnect structures in the local interconnect layer correspond to respective dies of the computing logic layer.

4. The device of claim 3, wherein a first of the plurality of dies has the same structure as a second of the plurality of dies.

5. The device of claim 2, wherein a global interconnect structure of at least one of the plurality of global interconnect layers is coupled between two of the plurality of dies.

6. The device of claim 2, wherein at least one transistor of the transistor layer forms a switch, the switch coupled between a first die and a second die of the plurality of dies.

7. The device of claim 1, further comprising a power via extending through the transistor layer to the computing logic layer.

8. The device of claim 7, further comprising a signal via extending through the transistor layer to the computing logic layer.

9. The device of claim 1, wherein the transistor layer comprises thin-film transistors (TFTs).

10. The device of claim 1, wherein the transistor layer comprises a substantially monocrystalline material having a grain size of at least 100 nm.

11. The device of claim 10, further comprising a bonding layer coupling the transistor layer to one of the plurality of global interconnect layers.

12. The device of claim 1, wherein a cross-section of a global interconnect structure in one of the plurality of global interconnect layers has a back side parallel to the computing logic layer and a front side parallel to the computing logic layer, the front side closer to the computing logic layer than the back side, wherein a length of the back side is longer than a length of the front side.

13. The device of claim 1, wherein a first dielectric material in the first of the plurality of global interconnect layers is different from a second dielectric material in the second of the plurality of global interconnect layers.

14. The device of claim 13, wherein the first dielectric material has a first dielectric constant, and the second dielectric material has a second dielectric constant different from the first dielectric constant.

15. A backside interconnect assembly comprising:
a plurality of backside interconnect layers coupled to a back side of a logic layer; and
an active layer formed between a first of the plurality of backside interconnect layers and a second of the plurality of backside interconnect layers, the active layer comprising a plurality of transistors.

16. The backside interconnect assembly of claim 15, wherein the logic layer comprises a plurality of dies, and the plurality of backside interconnect layers couple a first die of the logic layer to a second die of the logic layer.

17. The backside interconnect assembly of claim 15, wherein a logic device in the active layer alternatively couples a first die of the logic layer to a second die of the logic layer or to a third die of the logic layer.

18. A device comprising:
a logic layer comprising a plurality of transistors;
a first interconnect layer coupled to a first side of the logic layer, the first interconnect layer comprising a first dielectric;
a second interconnect layer coupled to a second side of the logic layer, the second side opposite the first side, the second interconnect layer comprising a second dielectric different from the first dielectric; and
a transistor layer coupled to the second interconnect layer.

19. The device of claim 18, further comprising a third interconnect layer coupled to the transistor layer, the transistor layer between the second interconnect layer and the third interconnect layer.

20. The device of claim 18, wherein the logic layer comprises a plurality of dies.
